(19) United States
(12) Patent Application Publication
(10) Pub. No.: US 2003/0061704 A1
(43) Pub. Date: Apr. 3, 2003

(54) Method of bonding armature wires to a commutator segment

(76) Inventors: Jerome H. Nosal II, Wolverine Lake, MI (US); Darin Joseph Bremmer, Gregory, MI (US); Douglas Arthur Edgerton, Surrey (GB); Miklos Szakaly, Varpalota (HU); Gabor Bognar, Szekesfehervar (HU)

Correspondence Address: Brinks Hofer Gilson & Lione, P.O. Box 10395, Chicago, IL, 60610, US

(21) Appl. No.: 09/968,480

(22) Filed: Oct. 1, 2001

(51) Int. Cl. H01R 43/10; H01R 9/00; H05K 3/00

(52) U.S. Cl. 29/597; 29/843; 29/850; 29/854

(57) ABSTRACT

The present invention is generally directed towards a method of bonding a pair of conductor wires to a commutator segment in an armature assembly. The method of bonding generally comprises assembling a brazing coil around the inner conductor wire. The present method generates heat in the conductor wire and re-flows the brazing material. This is achieved by directing current through the conductor wires and the commutator segments.

### TECHNICAL FIELD OF THE INVENTION

This invention generally relates to electrical motors installed in a motor vehicle. More specifically, this invention relates to method of connecting armature conductors to an armature commutator segments.

### BACKGROUND OF THE INVENTION

In the usual construction of commutator-type dynamo-electric machines, such as alternators, generators and motors, the leads from the armature winding are soldered to the neck of the commutator segments. There are certain types of machines, however, such as direct-current generators for use on aircraft, in which high capacity is required but in which the size and weight of the machine must be kept small. Such machines, therefore, must be capable of delivering relatively large currents for their physical size, and certain parts of such machines may reach rather high temperatures and velocity in service. It has been found that the commutators sometimes reach temperatures and velocity in service which are high enough to cause eventual failure of conventional hot upset and or soldered connections of the armature conductor leads to the commutator bars or segments.

This problem in the prior art is overcome by brazing the armature conductor leads to the commutator segments. Brazing alloys suitable for this purpose have melting temperatures greater than 840° F., which is high enough to produce a reliable connection which will not become fatigue even under the severe conditions of service. The use of such high-melting temperature alloys, however, introduces a difficult problem in making the brazed connection to the commutator segments. Currently, the typical process of bonding the armature conductor wires to the commutator is by hot upset and or solder of the conductor wires into slots of a commutator having a riser or brazing by means of foil wrap, wire feed, or pastes. The hot upset process alone results in a mechanical bond that carries the high current of the motor. Hot upset process also requires much heat and force, typically greater than 250 lbs., and is known to induce failures to the commutator that can be undetected. Additionally, because of the heat and pressure, electrode life is typically very limited.

Therefore, there is a need in the industry to provide a reliable bond between the armature conductor wires and a commutator segments. There is also a need for a process of brazing that can withstand the centrifugal forces generated by the high revolutions of the armature. Additionally, the current processes utilize materials that contain more than 5% silver , require more processing steps or even more processing times. In addition, the use of high silver content in the brazing material there by driving the cost of manufacturing armature assembly higher.

### SUMMARY OF THE INVENTION

The present invention overcomes the disadvantages of the prior art by providing a brazed bond between two armature conductor wires and segments of a commutator.

In one aspect of the invention a braze material in form of a wire with an inside diameter creates an interference fit with the conductor wires. In another aspect of the invention, through processing, current is directed through the two conductor wires and the commutator segment. The brazing material re-flows creating a bond between the conductor wires and the commutator segments. In another aspect of the invention, the brazing coil used has a low silver content. In yet another aspect of the current invention, the process of brazing the armature conductor wires to the commutator segment allows for the exact amount of braze material to be used in the brazing process.

Further features and advantages of the invention will become apparent from the following discussion and the accompanying drawings

### BRIEF DESCRIPTION OF THE DRAWINGS

FIG. 1 is a perspective view of a armature assembly;

FIG. 2 is a perspective view of the armature conductor wires with the brazing coil wound to the inner conductor wires;

FIG. 3 is a perspective view of the process of attaching the commutator segment to the armature conductor wires; and

FIG. 4 is a front view of the brazing material re-flowed to establish a bond between the conductor wires and the commutator segments.

### DETAILED DESCRIPTION OF THE PREFERRED EMBODIMENT

The following description of the preferred embodiment is merely exemplary in nature and is in no way intended to limit the invention or its application or uses.

Referring in particular to the drawings, an armature assembly incorporating the teachings of the present invention is shown and represented by reference numeral 10.

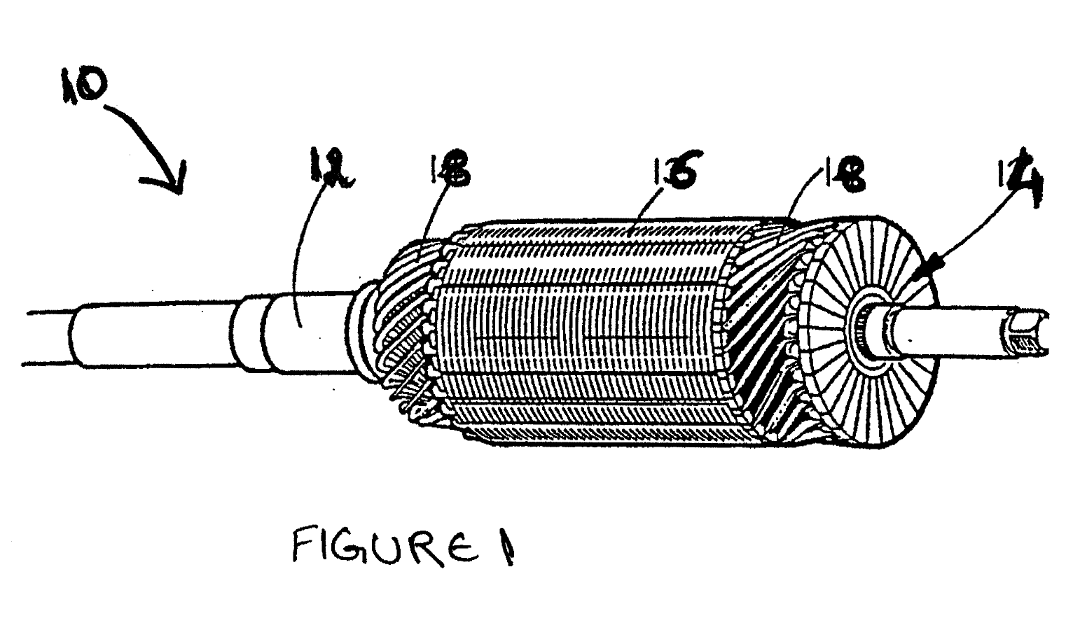

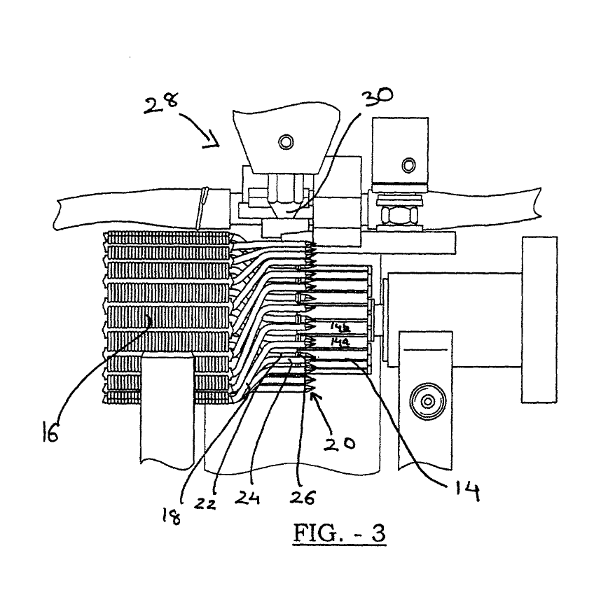

As shown in FIG. 1, the armature assembly includes a rotor shaft 12. At one end of the rotor shaft 12 is loaded a commutator 14. The commutator 14 is divided into number of segments (as shown in FIG. 3). For the sake of clarity the commutator segments have been labeled as 14a, 14b etc and are collectively referenced by reference numeral 14. As will be explained later, conductor wires will be bonded to the individual commutator segments 14. Also mounted non-rotatably on the rotor shaft 12 is a laminated armature core 16. The core 16 has axially extending slots that may be either closed or open. The slots of the core 16 receive armature winding conductor wires 18.

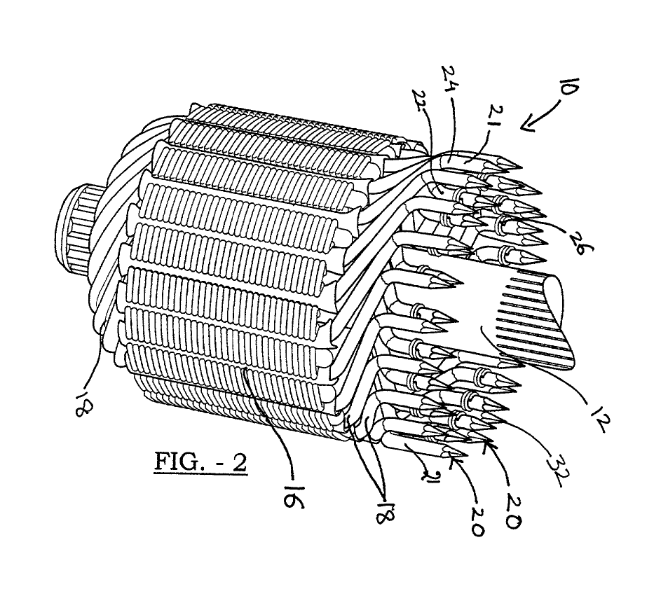

As shown in FIG. 2, the armature conductor wires 18 are inserted axially along the length of the slots. One end 20 of the armature conductor wires 18 is physically and electrically connected to the commutator segments 14 (not shown in FIG. 2). Preferably, the armature conductor wires 18 are in the form of a “hairpin” of bent copper wires. Preferably, the armature conductor wires 18 have a circular cross-section alternatively they may also have any suitable configuration such as a rectangular cross-section etc. The end 20 of the armature conductor wires 18 is stripped of any insulation material. The area where the insulation material is stripped from the end 20 is generally represented by reference numeral 21.

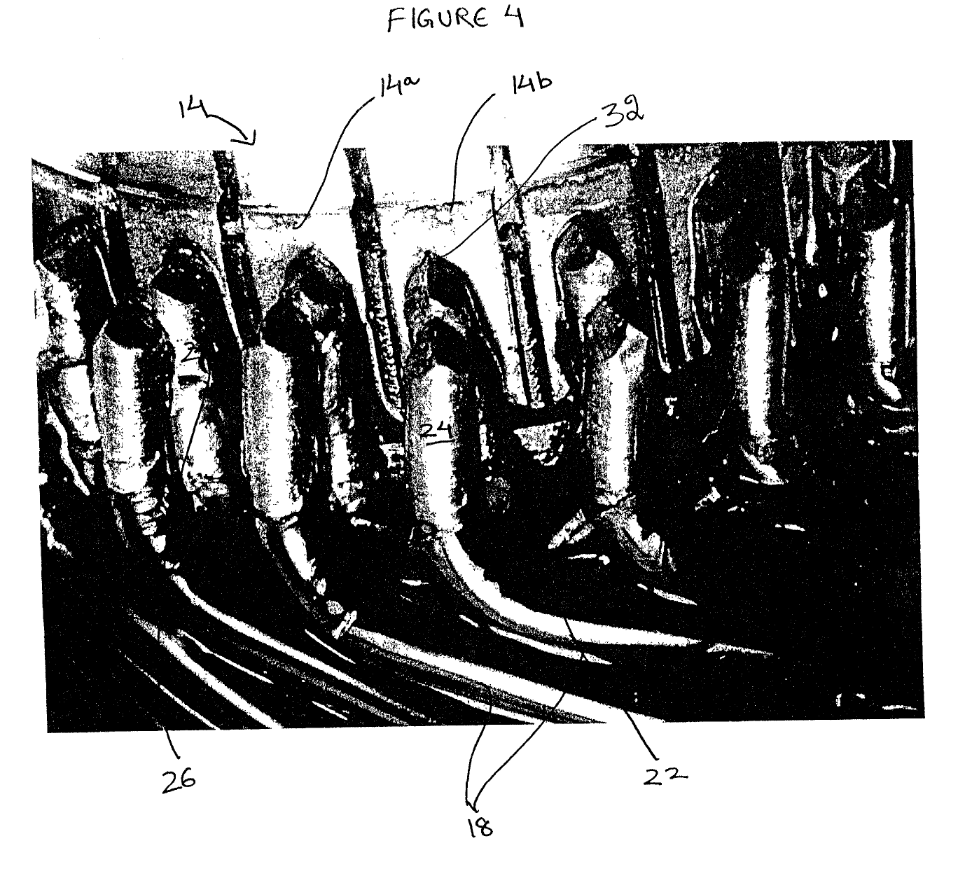

As shown in FIG. 2, the slots of the core 16 house a pair of conductor wires. As shown in FIGS. 4, a pair of armature conductor wires 18 are connected to each commutator segments 14. Preferably, one conductor wire 18 is disposed on top of another conductor wire 18 in a radial arrangement as shown in FIG. 2. The armature conductor wires 18 at end 20 preferably comprise an inner conductor wire 22 and an outer conductor wire 24. As shown in FIGS. 2 and 3, the inner conductor wire 22 is positioned between the outer conductor wire 24 and the commutator segments 14. As will be explained in the following paragraphs this arrangement of the inner conductor wire 22 and the outer conductor wire 24 with the commutator segments 14 will allow effective bonding between the conductor wires and the commutator segments 14.

As explained above, in order for the armature assembly 10 to perform effectively, it is important to establish a good physical and electrical connection between the commutator 14 and the end 20 of the armature conductor wires 18. The method of bonding the armature conductor wires 18 and the commutator segments 14 will now be explained in details with particular reference to FIGS. 2, 3 and 4.

As shown in FIG. 2, a brazing material 26, in the form of a wire is preferably used. Preferably, the brazing material 26 is preformed into coils using a simple spring winder. Preferably, the brazing material 26 selected comprises 5% silver, 6% phosphorous and remaining copper. Alternatively, other brazing material having different material composition may also be used.

As shown in FIGS. 2 and 3, the brazing material 26 in form of wound coils is assembled or is wrapped around the inner conductor wire 22, in the stripped area 21. The inner diameter of the brazing material 26 is such that it creates an interference fit to the outer diameter of the inner conductor wire 22. Preferably, one and a half turns of the brazing material 26 is enough to bond the armature conductor wires 18 to the commutator segments 14. Alternatively, more of less of number of turns may be required to effectively bond the inner conductor wire 22 to the outer conductor wires 24 and to the commutator segments 14.

As shown in FIG. 3, preferably, the commutator 14 is assembled to the shaft 12 of the armature assembly, after the brazing material 26 is assembled to the inner conductor wire 22. A machine consisting of a weld controller used to melt the brazing material 26. The machine is generally represented by reference numeral 28 in FIG. 3. The machine 28 comprises a welding electrode 30. Preferably, the welding electrode 30 used in the present invention is tungsten electrode. A tungsten electrode is preferred since tungsten has more resistance than copper and heat is generated faster. A tungsten electrode heats from electrode down and prevents annealing of the commutator segments 14. Alternatively, other electrodes made of other metals may be used.

As shown in FIGS. 3 and 4, as the welding electrode 30 contacts the outer conductor wire 24, current is directed through the outer conductor wire 24 to inner conductor wire 22 and the commutator segments 14. The current passing through the stripped area 21 of the armature conductor wires 18 and the commutator segment 14 generates sufficient heat to melt the brazing material 26 by convection. As the brazing material 26 melts, it wets the entire stripped area 21 of the inner conductor wire 22 thereby bonding the inner conductor wire 22 to the outer conductor wire 24 and the commutator segments 14. Preferably, the amount of current that is passed through the electrode is in the range of 2600 amps to 3200 amps. As shown in FIG. 4, the brazing material 26 melts and re-flows in the direction of the of the greatest heat gradient, i.e., towards the welding electrode 30. As the brazing material 26 melts and re-flows in the direction of the welding electrode, it bonds the inner conductor wire 22 to the outer conductor wire 24 and to the commutator segments 14. Since the current is passed through the stripped area 21 of the armature conductor wires 18 and the commutator segments 14, it avoids the problem of overheating and annealing of commutator segments 14. Alternatively, current may also be passed through the brazing material 26 itself.

As shown in FIG. 2, the brazing material 26 is attached to the inner conductor wire 22 at the farthest end. This is to allow room for the welding electrode 30 to clear the area of the brazing material 26 so that current can be directed through the outer conductor wire 24 to the inner conductor wire 22, and the commutator segments 14. Preferably, as shown in FIG. 2, the brazing material 26 is attached just below the nail point end 32 of the inner conductor wire 22. Preferably, the amount of insulation material stripped from the end 20 is such that the area the welding electrode 30 covers does not overlap the area the brazing material 26 covers. Preferably, the welding electrode 30 and the brazing material 26 cover ¾ of the total stripped area 21 of the inner conductor wire 22. Preferably a ¼ of the gap is left between the brazing material 26 and the welding electrode 30 to ensure that the brazing material 26 melts and re-flows in the direction of the of the greatest heat gradient, i.e. towards the welding electrode.

As any person skilled in the art will recognize from the previous description and from the figures and claims, modifications and changes can be made to the preferred embodiment of the invention without departing from the scope of the invention as defined in the following claims.

What is claimed is:

1. A method of manufacturing an armature assembly, the method comprising the steps of:
providing a shaft;
mounting a laminated armature core non-rotatably on the shaft, wherein the armature core has a plurality of axially extending slots;
inserting conductor wires into the slots, wherein the conductor wires have at least one lead end;
winding a brazing material into a brazing coil;
assembling the brazing coil around the at least one lead end, such that the brazing coil provides an interference fit with the at least one lead end of the conductor wires;
providing a commutator at one end of the shaft, wherein the commutator comprises a plurality of commutator segments;
positioning the at least one lead end with the brazing coil against the commutator segments;
directing a current through the at least one lead end; and
melting and re-flowing the brazing coil such that the at least one lead end of the conductor wire is bonded to the commutator segments.

2. The method of claim 1 wherein the brazing coil is made from 5% silver, 6% phosphorous and 89% copper.

3. The method of claim 1 wherein before the step of assembling the brazing coil comprises the step of stripping insulation material from the at least one lead end of the conductor wires.

4. The method of claim 1 wherein the brazing coil covers one-forth of the at least one lead end of the conductor wires.

5. The method of claim 1 wherein the step of directing current further comprises the steps of:
providing an electrode; and
establishing a contact between the electrode and the at least one lead end of the conductor wire.

6. The method of claim 5 wherein the electrode is made of tungsten.

7. The method of claim 1 wherein the diameter of the brazing coil is at least 0.020 inches.

8. The method of claim 1 wherein the step of directing current comprises passing current in the range of 2600 amps to 3200 amps.

9. A method of manufacturing an armature assembly, the method comprising:
providing a shaft;
mounting an armature laminated core non-rotatably on the shaft, wherein the laminated core has axially extending slots;
inserting plurality of conductor wires into the slots wherein the conductor wires have an inner lead end and an outer lead end;
winding a brazing material into a brazing coil;
assembling the brazing coil around the inner lead end such that the brazing coil creates an interferences fit with an outer diameter of the inner lead end;
attaching a commutator at one end of the shaft, wherein the commutator has a plurality of commutator segments;
positioning the inner lead end with the brazing coil adjacent the commutator segments and the outer lead end;
directing current through the outer lead end to the inner lead end and the commutator segments;
melting and re-flowing the brazing coil; and
bonding the inner lead end with the outer lead end and the commutator segments.

10. The method of claim 9 wherein the brazing coil is made from 5% silver, 6% phosphorous and 89% copper.

11. The method of claim 9 wherein before the step of assembling the brazing coil comprises the step of stripping insulation material from the inner lead end and the outer lead end.

12. The method of claim 9 wherein the brazing coil covers one-forth of the inner lead end.

13. The method of claim 9 wherein the step of directing current further comprises the step of:
providing an electrode; and
establishing a contact between the electrode and the outer lead end.

14. The method of claim 13 wherein the electrode is made of tungsten.

15. The method of claim 9 wherein the diameter of the brazing coil is at least 0.020 inches.

16. The method of claim 9 wherein the step of directing current comprises passing current in the range of 2600 amps to 3200 amps.

17. A method of bonding at least one lead end of a conductor wire to a commutator segment, the method comprising:
positioning the at least one lead end adjacent the commutator segment;
assembling a brazing coil having a maximum of 5% silver content around the at least one lead end such that the brazing coil creates an interferences fit with the at least one lead end;
directing current through the commutator segment and the at least one lead end;
melting and re-flowing the brazing coil; and
bonding the at least one lead end with the commutator segment.

18. The method of claim 17 wherein the brazing coil is made from 5% silver, 6% phosphorous and 89% copper.

19. The method of claim 17 wherein the brazing coil covers one-forth of the at least one lead end of the conductor wire.

20. The method of claim 17 wherein the step of directing current further comprises the step of:
providing an electrode; and
establishing a contact between the electrode and the at least one lead end of the conductor wire.

21. The method of claim 20 wherein the electrode is made of tungsten.

22. The method of claim 17 wherein the diameter of the brazing coil is at least 0.020 inches.

23. The method of claim 17 wherein the step of directing current comprises passing current in the range of 2600 amps to 3200 amps.
